(19) United States
(12) Patent Application Publication
(10) Pub. No.: US 2016/0211219 A1
(43) Pub. Date: Jul. 21, 2016

(54) SEMICONDUCTOR DEVICE WITH AT LEAST ONE TRUNCATED CORNER AND/OR SIDE CUT-OUT

(71) Applicant: MELEXIS TECHNOLOGIES NV, Tessenderlo (BE)

(72) Inventors: Luc BUYDENS, Kasterlee (BE); Sam MADDALENA, Zelem (BE); Petko NEDELEV, Sofia (BG)

(21) Appl. No.: 14/991,035

(22) Filed: Jan. 8, 2016

(30) Foreign Application Priority Data
Jan. 17, 2015 (GB) 1500785.9

(51) Int. Cl. H01L 23/544; H01L 21/48; H01L 21/78

(52) U.S. Cl. CPC H01L 23/544; H01L 21/78; H01L 21/4853; H01L 2223/54426; H01L 2223/5448

(57) ABSTRACT

A method of producing a substantially rectangular semiconductor device having at least one corner truncation or corner cut-out or side cut-out, comprises: a) providing a semiconductor substrate; b) making at least one opening through the substrate by means of etching; and c) cutting the substrate along a first pair of parallel lines, and along a second pair of parallel lines perpendicular to the first pair. At least one line of the first/second pair passes through said opening. Two lines may pass through said opening. More than one opening may be provided for said device. The opening may be located at a corner or on a side of the otherwise rectangular device. The etching may be any combination of existing isotropic/anisotropic front/back etching techniques.

### FIELD OF THE INVENTION

The present invention relates in general to the field of semiconductor processing and packaging. More in particular, the invention relates to the mounting of a semiconductor device (e.g. a semiconductor die) having at least one truncated corner or corner cut-out or side cut-out, and to methods of producing same. The invention also relates to a method of mounting such a device in a TO (transistor outline) package, and to a TO package comprising such a semiconductor device.

### BACKGROUND OF THE INVENTION

Methods of making semiconductor wafers, e.g. silicon wafers, comprising a plurality of semiconductor devices, are known in the art. The semiconductor wafer is separated into so called “semiconductor dies” before being packaged. Wafer dicing is a process by which the “semiconductor dies” are separated from the semiconductor wafer following the processing of the wafer. The dicing process can e.g. be accomplished by mechanical sawing or by laser cutting. Following the dicing process the individual semiconductor chips are encapsulated into chip carriers, a step known as “packaging”, and pins (or legs) of the package are electrically connected to specific locations on the die, e.g. by a step known as “wire bonding”. The packaged devices are then suitable for use as building blocks in electronic devices such as e.g. computers.

Many different types of packages exist. Suitable packaging is typically chosen depending on many factors, such as e.g. the size of the semiconductor die to be encapsulated, the number of pins (which in turn is dependent on the number of power and ground connections, and the number of signals to be input and/or output), environmental conditions (temperature, humidity, sealing, radiation, etc), the function of the electronic device (e.g. an IR sensor requires a window for passing IR light), etc. The sizes of the semiconductor die, as well as the type of the package, are important cost factors of the packaged electronic device.

### SUMMARY OF THE INVENTION

It is an object of embodiments of the present invention to provide a good method of manufacturing a semiconductor device (such as e.g. a semiconductor die, for instance a silicon die).

In particular, it is an object of embodiments of the present invention to provide a method of producing a substantially rectangular semiconductor device (e.g. silicon die) having at least one truncated or removed or cut-out corner and/or at least one side cut-out.

It is also an object of embodiments of the present invention to provide a method of mounting a substantially rectangular semiconductor device in a package having obstructions, whereby the area of the semiconductor device is larger than the area of the largest rectangular size without any truncations or cut-outs that would fit between the obstructions.

It is also an object of embodiments of the present invention to provide a semiconductor device having at least one corner truncation or corner cut-out or side cut-out.

It is also an object of embodiments of the present invention to provide a transistor outline package comprising such a semiconductor device having at least one corner truncation or corner cut-out or side cut-out.

These objectives are accomplished by a method and device according to embodiments of the present invention.

In a first aspect, the present invention provides a method of producing a substantially rectangular semiconductor device having at least one corner truncation and/or at least one corner cut-outs and/or at least one side cut-out, comprising the steps of: a) providing a semiconductor substrate; b) making at least one opening through the semiconductor substrate by means of etching; c) cutting the substrate along at least a first pair of parallel lines, and along a second pair of parallel lines perpendicular to the first pair, wherein at least one line of the first pair and/or the second pair passes through said opening.

By cutting the substrate along a first pair of lines, and along a second pair of lines which is perpendicular to the first pair of lines, a substantially rectangular device is obtained (that is, without taking the opening into account, it would be rectangular or square).

It is advantageous to provide an opening (i.e. a through-hole) in the substrate, and to cut the substrate along a line passing through said opening, because in this way a device with one or more truncated corners and/or corner cut-outs and/or side cut-outs can be achieved.

It is an advantage of a substantially rectangular semiconductor device (e.g. a semiconductor die such as for instance a silicon die) having one or more truncated corners and/or one or more corner cut-outs and/or one or more side cut-outs, because such a device can be mounted in a space with one or more obstructions corresponding to the locations of the truncated corner(s) and/or corner cut-outs and/or side cut-out(s). By removing part of the substrate, in particular at a corner or an side, a kind of perforation or incision is provided, allowing the size of the rest of the rectangular shape to be larger than the size of a perfect rectangle that can fit in the same space, but does not have such cut-out(s) or truncation(s) and being oriented in the same direction.

It is an advantage of the method that said at least one opening is made by means of etching the substrate, because it ensures high precision and accuracy, with a minimal risk of damaging the rest of the substrate.

It is a further advantage of the method that devices with a relatively complex shape, in particular e.g. a concave shape, can be obtained. It may be technically very difficult or even impossible to obtain such a shape using another method, in particular laser cutting or mechanical sawing, which typically only works in straight lines.

This method may be ideally suited for producing a semiconductor device such as e.g. a silicon die, that has to fit in a so called metal can Transistor Outline package (also known as metal can TO-package), e.g. a “TO-3” package having three legs and three corresponding wire connection points forming obstructions in the encapsulated area. By providing said corner truncations and/or corner cut-outs and/or side cut-outs, a semiconductor device with an increased area can be provided, on which area electronic circuitry can be provided, without having to rotate the device, and that can still fit in the package. For example, in an optical device the chip must be aligned in a certain direction for it to fit the application. Moreover, such a device could be mounted in the TO-can package in a plane substantially perpendicular to the legs, rather than in a direction parallel to the legs.

It is particularly advantageous to use this method for making a MEMs semiconductor device (Micro Electro Mechanical Systems) that has to fit in a TO-can package, because the process for making a MEMs device typically already has one or more etching steps, hence the etching of the opening can be incorporated in the already existing methods of forming MEMs, with the important difference that now a through-hole is made in the substrate, in contrast to prior art methods, where only a blind hole is made (not a through-hole), or other methods where a through hole is made in the substrate, but where that hole is not subsequently cut through during the dicing step.

In an embodiment of the method, in step c) the at least one opening is passed by at least one line of the first pair, and also by at least one line of the second pair.

In this embodiment two perpendicular lines pass through the same opening. In absence of the opening, the lines would form simply a 90° corner of the rectangular device, but now, due to the opening, a rectangle with a truncated corner is formed instead.

It is an advantage of providing a device with a truncated corner in that the corner truncation may be used to avoid an obstruction. In this way a semiconductor device can be provided with an increased area (hence more functionality), without having to rotate the device (e.g. with respect to an axis perpendicular to a local surface).

It is an advantage of such a device in that it can be mounted in locations with one or more obstructions.

It is an advantage that such a device may be mountable in a smaller package.

It is an advantage that such a device can be mounted on the mounting surface of the package (e.g. in a plane perpendicular to the package legs) rather than in another direction (e.g. in a plane parallel to the legs).

In an embodiment, step b) comprises making at least two openings through the semiconductor substrate by means of etching; and in step c) each opening is passed by at least one line of the first and/or second pair.

The phrase “the opening is passed by at least one line” is equivalent to the phrase “at least one line intersects the opening”.

By providing at least two openings, it is e.g. possible to make a substantially rectangular semiconductor device (e.g. silicon die) with two (or more) corner truncations (or corner cut-outs), or to make a substantially rectangular semiconductor device with two (or more) side cut-outs, or to make a substantially rectangular semiconductor device with one (or more) truncated corners and one (or more) side cut-outs.

Such a device may be very well suited for being mounted between two obstructions.

In an embodiment, step b) comprises making at least three openings through the semiconductor substrate by means of etching; and in step c) each opening is passed by at least one line of the first and/or second pair.

With this method, it is e.g. possible to make a substantially rectangular semiconductor device (e.g. a semiconductor die such as for instance a silicon die) with three corner truncations, or a substantially rectangular semiconductor device with three side cut-outs, or a substantially rectangular semiconductor device with one corner truncation and two side cut-outs, or a substantially rectangular semiconductor device with two corner truncations and one side cut-out.

Such a device may be very well suited for being mounted between three obstructions.

In an embodiment, step b) comprises making at least four openings through the semiconductor substrate by means of etching; and in step c) each opening is passed by one line of the first pair and by one line of the second pair.

With this method, it is e.g. possible to make a substantially rectangular semiconductor device with four truncated corners, or a substantially rectangular semiconductor device with four side cut-outs, or a substantially rectangular semiconductor device with one truncated corner and three side cut-outs, or a substantially rectangular semiconductor device with two truncated corners and two side cut-outs, or a substantially rectangular semiconductor device with three truncated corners and one side cut-out.

Such a device may be very well suited for being mounted between four obstructions.

In an embodiment, the at least one opening has a substantially triangular or rectangular or square or circular cross-section in a plane parallel to the substrate.

In fact, an opening of substantially any arbitrary shape can be obtained, by e.g. exposing the entire area to the etchant, or by exposing only the perimeter of the desired opening to the etchant. This can be achieved by any known technique.

In an embodiment, the opening has a substantially square shape, and the sides of said square cross-section are substantially parallel to the lines of step c).

This way, a substantially square semiconductor device with substantially square corner and/or side cut-outs may be obtained.

In an embodiment, the opening has a substantially square shape, and the sides of said square cross-section have an angle of about 45° with respect to the cutting lines of step c).

This way, a substantially square semiconductor device with substantially triangular corner and/or side cut-outs may be obtained.

In an embodiment, step b) comprises making the at least one opening using an isotropic etching technique.

In an embodiment, step b) comprises making the at least one opening using an anisotropic etching technique.

It is an advantage of using anisotropic etching in that it is much easier to control or to prevent under-etching, hence the risk of damaging the rest of the integrated circuit is reduced.

Anisotropic etching may be performed from the front side of the substrate, by using e.g. TMAH as an etchant. Alternatively or additionally anisotropic etching may be performed from the back side of the substrate, by using e.g. DRIE or KOH as an etchant.

In an embodiment, step b) comprises making the at least one opening by using at least two different etching steps selected from the group consisting of isotropic front etching, isotropic back etching, anisotropic front etching and anisotropic back etching.

In this embodiment, the at least one opening is not formed in a single etching step, but as a cumulative result of at least two partial etching steps. In this way, the time required for etching through the entire substrate thickness can be divided over more than one time-slot.

For example, in a first etching step a MEMs structure could be made, and at the same time a partial opening is made at a corner or at a side, and a second etching step is used to break through the wafer.

In a second aspect, the present invention provides a semiconductor device having at least one corner truncation and/or at least one corner cut-out and/or at least one side cut-out, primarily formed by etching.

The semiconductor device can be manufactured using a method according to any of the previous claims.

In a third aspect, the present invention provides a method of mounting, in a transistor outline package, a substantially rectangular semiconductor device having at least one corner truncation and/or at least one corner cut-out and/or at least one side cut-out, the method comprising: a) providing a transistor outline package, having at least two elongated legs and at least two corresponding internal wire connection points; b) providing a substantially rectangular semiconductor device having at least one truncated corner and/or at least one corner cut-out and/or at least one side cut-out, made by a method according to the first aspect; c) positioning the semiconductor device in a plane substantially perpendicular to the elongated legs of the transistor outline package, such that at least one of the wire connection points is located adjacent the at least one corner truncation and/or the at least one corner cut-out and/or the least one side cut-out.

After mounting the semiconductor device to the package, each of the wire connection points is then typically electrically connected to a particular area of the semiconductor device, using known techniques, such as bonding.

It is an advantage of using a substantially rectangular semiconductor device having one or more truncated corners and/or one or more corner cut-outs and/or one or more cut-outs in one or more of its sides, in that the effective area (i.e. the area where integrated circuits can be made) of the device can be larger than that of a rectangular semiconductor device without such corners or sides, while the device still fits in the package without rotation.

It is an advantage of mounting the semiconductor device in the TO-can package in a plane substantially perpendicular to the elongated legs, rather than in a direction parallel to the elongated legs.

In an embodiment the number of truncated corners and/or corner cut-outs and/or side cut-outs corresponds in number and position with said wire connection points, but that is not absolutely required, more truncated sides and/or side cut-outs may be foreseen, for example to make a design that fits is more than one metal can TO package.

In a fourth aspect, the present invention provides a transistor outline package comprising a semiconductor device mounted therein as described according to the third aspect.

The semiconductor device can be mounted in the transistor outline package using a method according to the third aspect.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 shows a metal transistor outline package with four legs, and comprising a (relatively small) square or rectangular semiconductor device, known in the art. For illustrative purposes, the metal package is shown as if it were transparent.

FIG. 2 shows the metal transistor outline package of FIG. 1, from below.

FIG. 3 shows a semiconductor wafer, for instance silicon wafer, with a plurality of semiconductor dies, e.g. silicon dies.

FIG. 4 shows the mounting surface of the transistor outline package of FIG. 1 in enlarged top view, with four wire connection points (indicated as black dots), and with a rectangular semiconductor device arranged between the wire connection points.

FIG. 5 shows a variant of the mounting surface of the transistor outline package of FIG. 4, comprising a larger semiconductor device arranged between the wire connection points.

FIG. 6 shows an example of substantially rectangular semiconductor device with four truncated corners, according to an embodiment of the present invention. The device is mounted to the mounting surface of the transistor outline package of FIG. 4, according to another embodiment of the present invention.

FIG. 7 shows another example of a substantially rectangular semiconductor device with four truncated corners, according to embodiments of the present invention. The device is mounted to the mounting surface of the transistor outline package of FIG. 4, according to another embodiment of the present invention.

FIG. 8 shows an example of a substantially rectangular semiconductor device with two side cut-outs, according to embodiments of the present invention. The device is mounted to the mounting surface of a transistor outline package with two wire connection points (corresponding to two legs), according to another embodiment of the present invention.

FIG. 9 is a flow chart illustrating a method of producing a substantially rectangular semiconductor device having at least one truncated corner and/or at least one side cut-out, according to an aspect of the present invention.

FIG. 10 (a) to FIG. 10(d) illustrate the steps (a) to (c) of the method shown in FIG. 9. FIG. 10(a) shows a substrate with a semiconductor region (dark gray). FIG. 10(b) shows the substrate of FIG. 10(b) with an opening through the substrate. FIG. 10(c) illustrates how the substantially rectangular part can be cut out of the substrate. FIG. 10(d) shows the substantially rectangular semiconductor device with one truncated corner, according to an embodiment of the present invention.

FIG. 11(a) to FIG. 11(d) is a variant of the method illustrated in FIG. 10(a) to FIG. 10(d), whereby two openings are made in the substrate, resulting in a substantially rectangular semiconductor device having two truncated corners, as an embodiment of a method and a semiconductor device according to the present invention.

FIG. 12(a) to FIG. 12(d) is another variant of the method illustrated in FIG. 10(a) to FIG. 10(d), whereby three openings are made in the substrate, resulting in a substantially rectangular semiconductor device having three truncated corners, as an embodiment of a method and a semiconductor device according to the present invention.

FIG. 13(a) to FIG. 13(d) is another variant of the method illustrated in FIG. 10(a) to FIG. 10(d), whereby four openings are made in the substrate, resulting in a substantially rectangular semiconductor device having four truncated corners, as an embodiment of a method and a semiconductor device according to the present invention.

FIG. 14(a) to FIG. 14(d) is a variant of the method illustrated in FIG. 11(a) to FIG. 11(d), whereby the two openings have a different orientation compared to that of FIG. 11, resulting in a substantially rectangular semiconductor device having two corner cut-outs, as an embodiment of a method and a semiconductor device according to the present invention.

FIG. 15(a) to FIG. 15(d) is a variant of the method illustrated in FIG. 12(a) to FIG. 12(d), whereby the three openings have a different orientation compared to that of FIG. 12, resulting in a substantially rectangular semiconductor device having three corner cut-outs, as an embodiment of a method and a semiconductor device according to the present invention.

FIG. 16(a) to FIG. 16(d) is a variant of the method illustrated in FIG. 13(a) to FIG. 13(d), whereby the four openings have a different orientation compared to that of FIG. 13, resulting in a substantially rectangular semiconductor device having four corner cut-outs shown in FIG. 16(d), as an embodiment of the present invention.

FIG. 17(a) to FIG. 17(d) is a variant of the method illustrated in FIG. 14(a) to FIG. 14(d), whereby the two openings have a different position compared to that of FIG. 14, resulting in a substantially rectangular semiconductor device having two side cut-outs, as an embodiment of a method and a semiconductor device according to the present invention.

FIG. 18(a) to FIG. 18(d) is a variant of FIG. 17(a) to FIG. 17(d), whereby the two openings have a different orientation compared to that of FIG. 17, resulting in a substantially rectangular semiconductor device having two side cut-outs, as an embodiment of a method and a semiconductor device according to the present invention.

FIG. 19(a) to FIG. 19(d) is a variant of the method illustrated in FIG. 12(a) to FIG. 12(d), whereby the three openings have a different position compared to that of FIG. 12, resulting in a substantially rectangular semiconductor device having two truncated corners and one side cut-out, as an embodiment of a method and a semiconductor device according to the present invention.

FIG. 20(a) to FIG. 20(d) is a variant of the method illustrated in FIG. 14(a) to FIG. 14(d), whereby one of the openings has a different position, resulting in a substantially rectangular semiconductor device having one corner cut-out and one side cut-out, as an embodiment of a method and a semiconductor device according to the present invention.

FIG. 21 shows an opening pattern that can be used in a method to produce four semiconductor dies, for instance silicon dies, each having one truncated corner, according to embodiments of the present invention. The openings have a triangular cross-section in a plane parallel to the substrate.

FIG. 22 shows an opening pattern that can be used in a method to produce four semiconductor dies, such as silicon dies, each having four corner cut-outs, according to embodiments of the present invention. The openings have a circular cross-section in a plane parallel to the substrate.

FIG. 23 shows an opening pattern that can be used in a method to produce four semiconductor dies, e.g. silicon dies, each having four corner cut-outs, according to embodiments of the present invention. The openings have a square cross-section in a plane parallel to the substrate, the sides of which square are parallel to the cutting lines.

FIG. 24 shows an opening pattern that can be used in a method to produce four semiconductor dies, e.g. silicon dies, each having one truncated corner, according to embodiments of the present invention. The openings have a square cross-section in a plane parallel to the substrate, the sides of which square show an angle of, in the embodiment illustrated, 45° with respect to the cutting lines; the present invention not being limited thereto.

It is to be noted that not all reference signs have been shown in each drawing, so as not to overload the drawings with too much information.

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

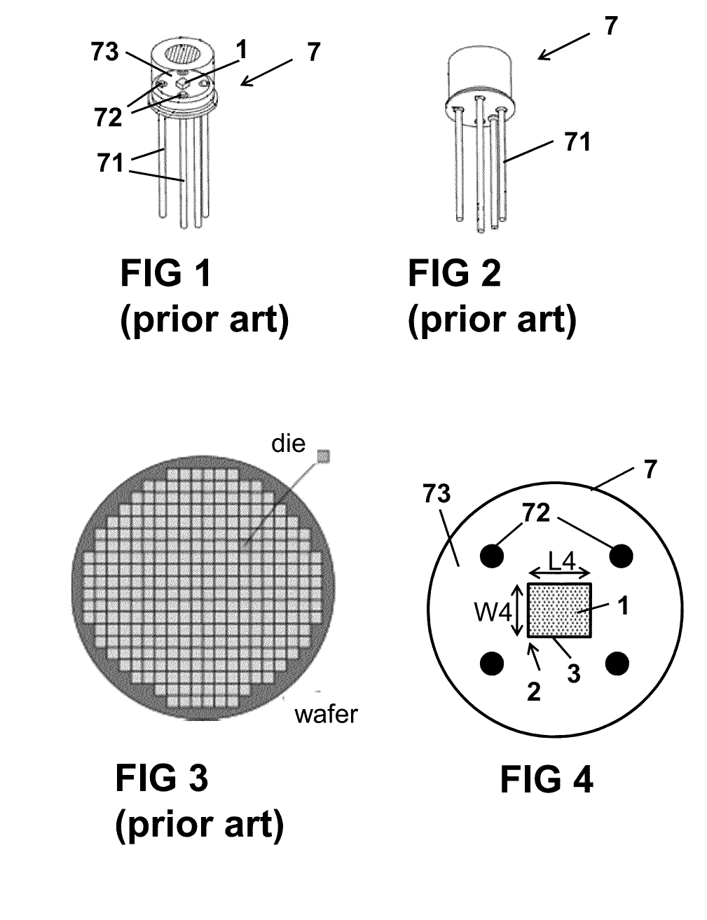

FIG. 1 shows a metal can IC package 7, also known as TO-package or Transistor Outline package, with four legs 71, and comprising a relatively small square or rectangular semiconductor device 1, as known in the art. It is to be noted that the metal package is shown as if it were transparent, for illustrative purposes only. As can be seen, the semiconductor device 1, e.g. silicon die, is arranged between four wire connection points 72, which are in fact part of the legs 71, or at least connected thereto. The semiconductor device 1 is mounted to the inner surface 73 of the package 7 using known techniques, such as e.g. by means of gluing. One of the advantages of a metal can package is that it can be hermetically sealed at high vacuum.

FIG. 2 shows the metal transistor outline package 7 of FIG. 1 from below. The metal can package 7 shown in FIG. 1 and FIG. 2 has four legs 71, and the present invention will be illustrated for this metal can package; however, the invention is not limited thereto, and can also be used for other metal can packages 7, for instance with only two legs 71, or with only three legs, or with more than four legs, e.g. five or six or even more legs. In fact, the present invention is not limited to metal can packages, and may also be useful to solve other packaging challenges, in particular packages having internal obstructions.

FIG. 3 shows a semiconductor wafer, for instance a silicon wafer, having a plurality of semiconductor dies, e.g. silicon dies, as is well known in the art. In the case illustrated, the dies are square, but that is not absolutely required, and dies can also be rectangular. After the semiconductor wafer is processed, the dies have to be separated, in a step generally known as “dicing of a semiconductor wafer”, wherein the semiconductor wafer is e.g. cut by means of laser cutting or mechanical sawing. The latter may be performed using a machine called a dicing saw.

FIG. 1 to FIG. 3 illustrate that the semiconductor industry is primarily targeted at making rectangular dies, and fitting those dies in packages. As far as is known to the inventors, the prior art does not provide cutting of a wafer into shapes other than square or rectangular shapes.

FIG. 4 shows the mounting surface 73 of the metal can transistor outline package 7 of FIG. 1 in enlarged top view, with four wire connection points 72 (indicated as black dots). A rectangular semiconductor device 1, e.g. rectangular silicon die, is arranged between the wire connection points 72. It has a rectangular shape with a length L4 and width W4. It has four corners 2 with an angle of 90°, and four sides 3 having the shape of straight lines. The inventors were concerned with the problem of fitting a semiconductor device, e.g. silicon die, having a larger size than the one shown in FIG. 4, in a metal can package 7, e.g. the package shown in FIG. 4.

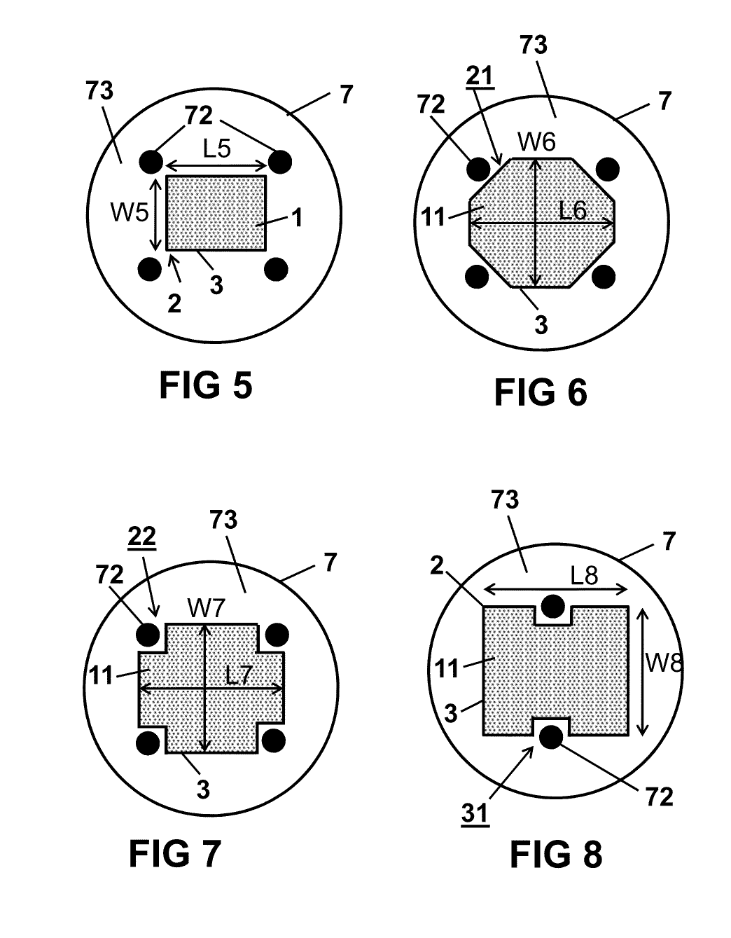

FIG. 5 shows a variant of the mounting surface 73 of the transistor outline package 7 of FIG. 4, comprising a somewhat larger semiconductor device 1 arranged between the wire connection points 72. It has four straight sides 3, four corners of 90°, and a length L5 and width W5 larger than the length L4 and width W4 of the semiconductor device of FIG. 4, but it can still be arranged between the four wire connection points 72 of the package 7. A skilled person desiring to increase the size of the semiconductor device 1, would either further increase the length L5, while maintaining the width W5, or further increase the width W5 while maintaining the length L5, but could not increase both, because then the semiconductor device would not fit between the wire connection points 72 anymore. Of course, he could try to turn the semiconductor device over 45°, but this is not always possible or desired when the semiconductor has to be aligned with the package for stability reasons or for optical alignment. So, one of the problems being addressed by the present invention is: how can the area of the semiconductor device 1 be increased, while still being able to fit it inside the (given) metal can package 7 between the wire connection points 72, and without rotating the device. As will be explained next, the present invention provides several possible solutions to this problem, e.g. by providing one or more truncated corners 21 instead of 90° corners, as illustrated for example in FIG. 6, or by providing one or more corner cut-outs 22 instead of the 90° corners, as illustrated for example in FIG. 7, or by providing one or more side cut-outs 31 rather than straight sides, as illustrated for example in FIG. 8, or by combinations thereof. These examples will be discussed in more detail next.

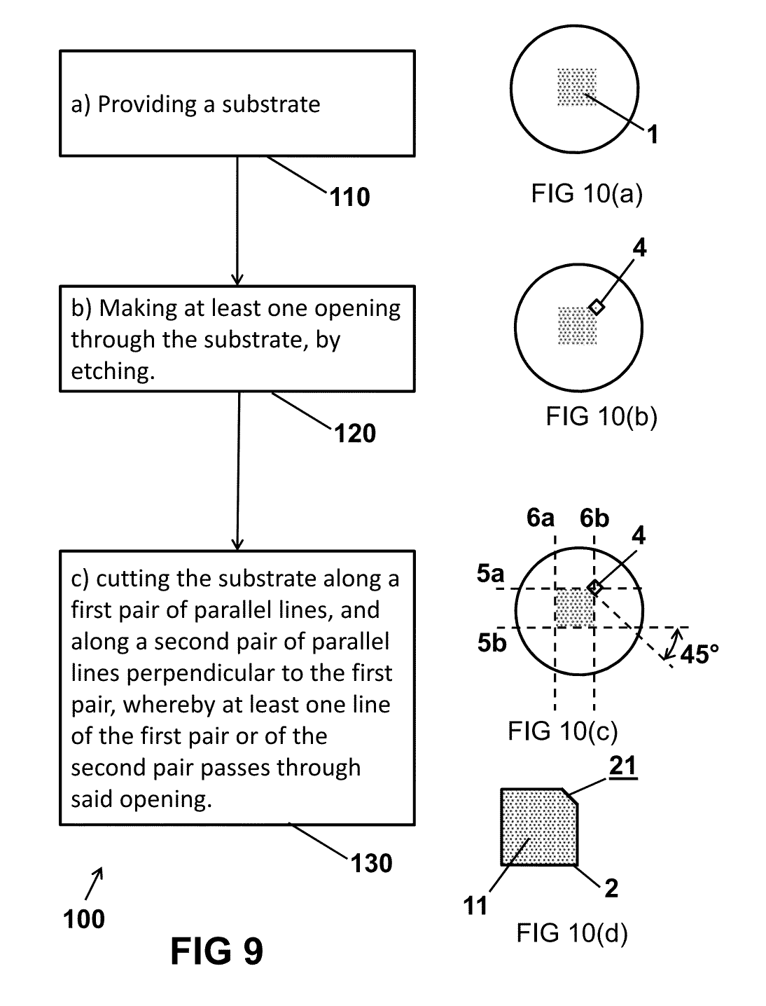

FIG. 6 shows an example of a substantially rectangular semiconductor device 11 with four truncated corners 21. The device 11 can then be mounted to the mounting surface 73 of the TO package of FIG. 4, and be arranged between the obstructions 72 without having being rotated. Comparison of FIG. 6 and FIG. 5 shows that the length L6 is larger than L5, the width W6 is larger than the width W5, and the corner cut-outs 21 are not large, thus the semiconductor area is increased, which additional area can be used for placing additional circuitry, or for fitting existing integrated circuit modules without redesign. Even though the wafer area might be less efficiently used than in the case of a complete rectangle, because of the lost space at the truncated corners 21, the cost advantage of being able to use a smaller (cheaper) package, may justify to do so. Hence, embodiments of the present invention allow the skilled person to make a trade-off. How the semiconductor device 11 with truncated corners 21 can be manufactured, will be described further, in relation to FIG. 9.

The embodiment shown in FIG. 6 is in effect an octagonal shape. In alternative embodiments (not shown), the semiconductor device could also have a hexagonal shape (if for example only two corners would be cut, while the other two corners would not), or a pentagon (if for example only a single corner would be cut, while the other three corners would not).

FIG. 7 shows another example of a substantially rectangular semiconductor device 11 of which the four (original) corners are removed by corner cut-outs 22. Like the device 11 shown in FIG. 6, also the device 11 of FIG. 7 can be mounted to the mounting surface 73 of the TO package 7 of FIG. 4, and can be arranged between the obstructions 72, without rotation of the device 11. Comparison of FIG. 7 and FIG. 5 shows that the length L7 is larger than L5, the width W7 is larger than the width W5, and the corner cut-outs 21 are not large, thus the semiconductor area is increased, which additional area can be used for placing additional circuitry, or for fitting existing integrated circuit modules without redesign. As stated above, the less efficient use of the wafer area may be justified by the ability to re-use existing integrated circuits and/or the ability to use a smaller/cheaper package. How this semiconductor device 11 with corner cut-outs 22 can be manufactured, will be described further, in relation to FIG. 9.

FIG. 8 shows yet another example of a substantially rectangular semiconductor device 11, with two side cut-outs 31, for fitting inside a package 7, e.g. a metal can TO package having two legs, and hence two corresponding wire connection points 72, preventing the size of the rectangular semiconductor device 1 in the prior art to be increased. By using the method of embodiments of the present invention, two side cut-outs 31 can be made in the sides of the otherwise rectangular shape, hence the overall area of the semiconductor device 11 can be increased beyond the area defined by the wire connection points 72.

FIG. 9 illustrates the process steps of a method 100 according to embodiments of the present invention of producing a substantially rectangular semiconductor device 11 having at least one corner truncation 21 or at least one corner cut-out 22 or at least one side cut-out 31. FIG. 10 illustrates the steps of the method on a semiconductor wafer. In step 110, a substrate is provided, e.g. a semiconductor wafer such as a silicon wafer. FIG. 10(a) shows a substrate with a semiconductor region (dark gray). This region may correspond to the area of the semiconductor die, e.g. silicon die, to be cut out later. In step 120, at least one opening 4 is made through the substrate. The opening 4 shown in FIG. 10(b) is a through hole having a square cross-section in a plane parallel to the substrate, but that particular shape is not absolutely required, and other shapes can be used as well, such as e.g. a triangular shape, or a circular shape, or a linear slit, etc. It is important, however, that the opening 4 is not a blind hole. According to embodiments of the invention, the opening 4 is made by way of etching. In step 130, the substrate, e.g. the semiconductor wafer, is then cut, e.g. using laser cutting, along a first pair 5 of parallel lines 5a, 5b, and along a second pair 6 of parallel lines 6a, 6b perpendicular to the first pair 5, whereby at least one of the lines 5a, 5b, 6a, 6b passes through said opening 4. The resulting semiconductor device is shown in FIG. 10(d). In the particular case shown, one of the corners of the otherwise rectangular semiconductor device is removed, in other words, the semiconductor device, e.g. silicon die 11 has three “normal” corners with a 90° angle, and one truncated corner 21. It is clear that the size and shape and position of the opening 4 determines how the corner is actually truncated. For example in the case illustrated, a square opening 4 was used oriented at an angle of 45° with respect to the cutting lines 5, 6, hence the corner is truncated at an angle of 45°. It is an advantage of embodiments of the present invention that the size, shape and position of the opening 4 can be used as parameters to optimize the final size and shape of the semiconductor device 11. Optimization of the size and shape of the semiconductor device 11 may include determining the largest semiconductor area which still fits within a pre-determined package.

Etching is a well-known technique in the semiconductor industry, and therefore need not be explained in more detail here. The technology used can be either a wet etching technique, like etching with KOH or dry etching technique like deep reactive ion etching (DRIE).

Different forms of etching can be used in a method according to embodiments of the present invention, e.g. isotropic etching from the front side of the substrate, anisotropic etching from the front side of the substrate, isotropic etching from the back side of the substrate, anisotropic etching from the back side of the substrate, or any combination thereof. Preferably, the etching of the opening 4 is not done in a dedicated process step, because that would increase the processing time and thus the processing cost, but preferably the opening 4 is etched during already existing etching steps for processing the semiconductor wafer. This is for example the case when making MEMs devices with a suspended structure, e.g. an infrared sensor having a suspended membrane (or diaphragm), the invention not being limited hereto.

It is noted that etching of a semiconductor substrate per se, is known in the art, e.g. for making a blind hole or a through hole, or a slit, or the like. Also cutting a substrate, e.g. dicing of a wafer along parallel lines, is known in the art. But in the present invention, first an opening is etched in a substrate, and then the substrate is cut through that opening, the form and size and position of the opening and the cutting lines together defining the perimeter of the semiconductor device that will finally be obtained. It is believed that this combination is not known in the art, and is also a non-obvious combination, especially because etching is a relatively slow process which occurs during the so called front-end processing of the wafer, whereas cutting is a relatively fast process, which happens during the so called back-end processing of the wafer.

Referring back to FIG. 9, the same method can be applied to make a large variety of substantially rectangular or square semiconductor devices 11, having one or more of its corners removed or truncated or cut-out, and/or having one or more cut-outs in one or more of its sides 3. Several particular examples will be described next, but the invention is not limited thereto.

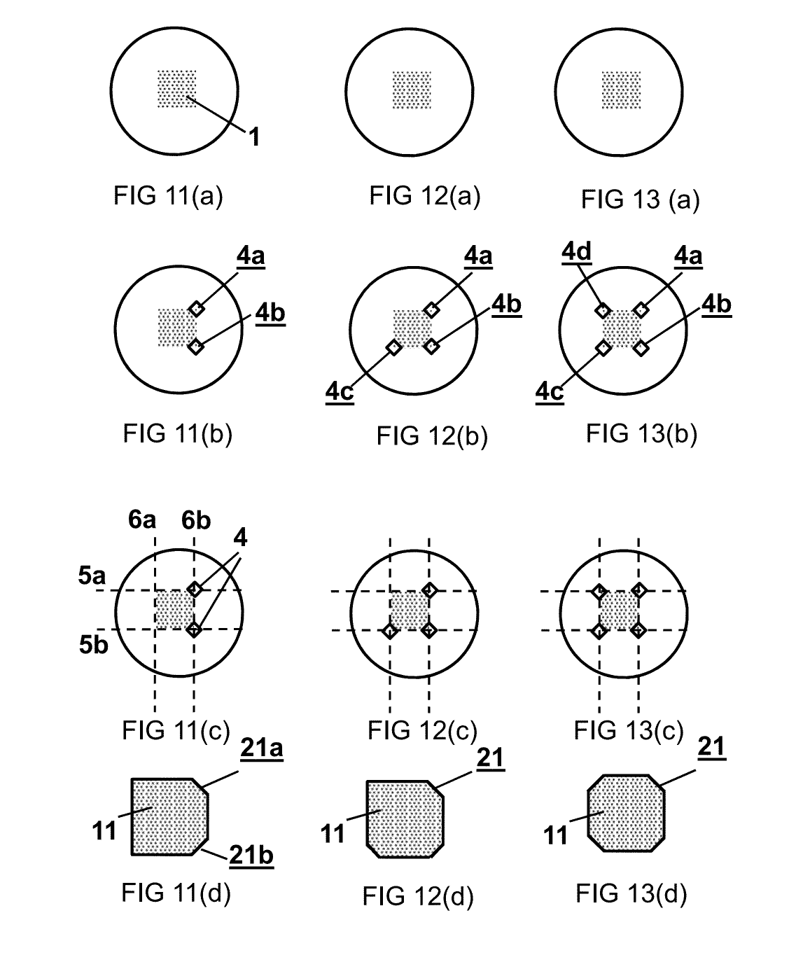

FIG. 11(a) to FIG. 11(d) is a variant of the method of FIG. 10(a) to FIG. 10(d), whereby two openings 4 are made in the substrate, resulting in a substantially rectangular semiconductor device 11 having two truncated corners 21a, 21b shown in FIG. 11(d).

FIG. 12(a) to FIG. 12(d) is another variant of the method of FIG. 10(a) to FIG. 10(d), whereby three openings 4 are made in the substrate, resulting in a substantially rectangular semiconductor device 11 having three truncated corners 21 shown in FIG. 12(d).

FIG. 13(a) to FIG. 13(d) is another variant of the method of FIG. 10(a) to FIG. 10(d), whereby four openings 4 are made in the substrate, resulting in a substantially rectangular semiconductor device 11 having four truncated corners 21 shown in FIG. 13(d).

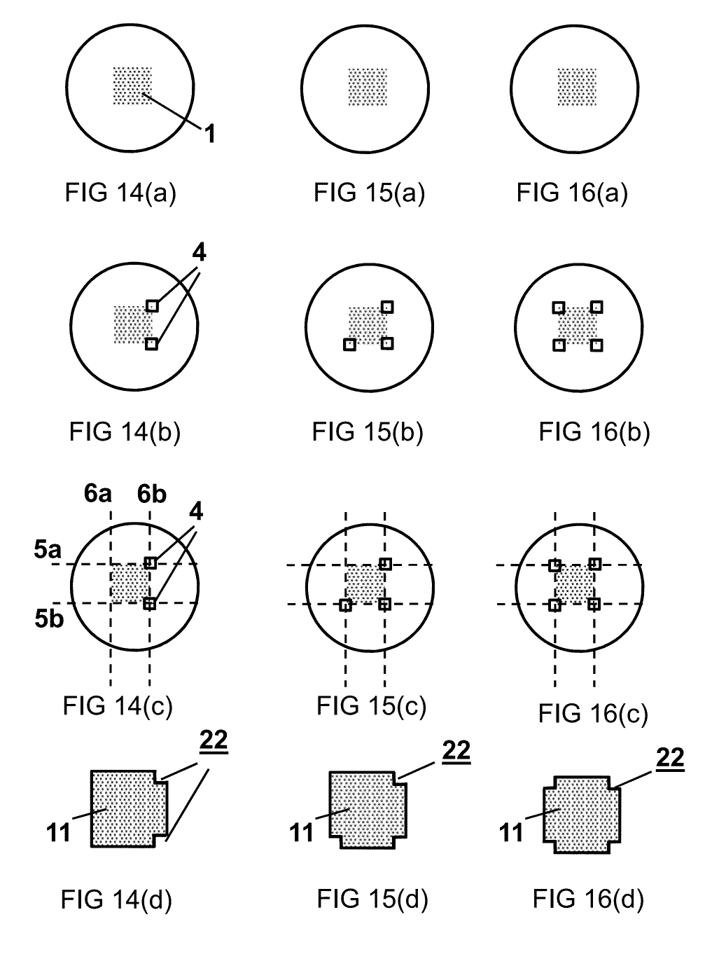

FIG. 14(a) to FIG. 14(d) is a variant of the method of FIG. 11(a) to FIG. 11(d), whereby the two openings 4 have a square cross-section in a plane parallel to the substrate, but the openings 4 have a different orientation, in the example of FIG. 14, the sides 41, 42 of the opening (in cross-section) are parallel to the cutting lines 5, 6, resulting in a substantially rectangular semiconductor device 11 having two corner cut-outs 22 shown in FIG. 14(d).

FIG. 15(a) to FIG. 15(d) is a variant of the method of FIG. 14(a) to FIG. 14(d), having three openings 4 instead of two, resulting in a substantially rectangular semiconductor device 11 having three corner cut-outs 22 shown in FIG. 15(d).

FIG. 16(a) to FIG. 16(d) illustrates a variant of the method of FIG. 14(a) to FIG. 14(d), having four openings 4 instead of two, resulting in a substantially rectangular semiconductor device 11 having four corner cut-outs 22 shown in FIG. 16(d).

In another variant of FIG. 14 (not shown), only one of the corners is cut-out.

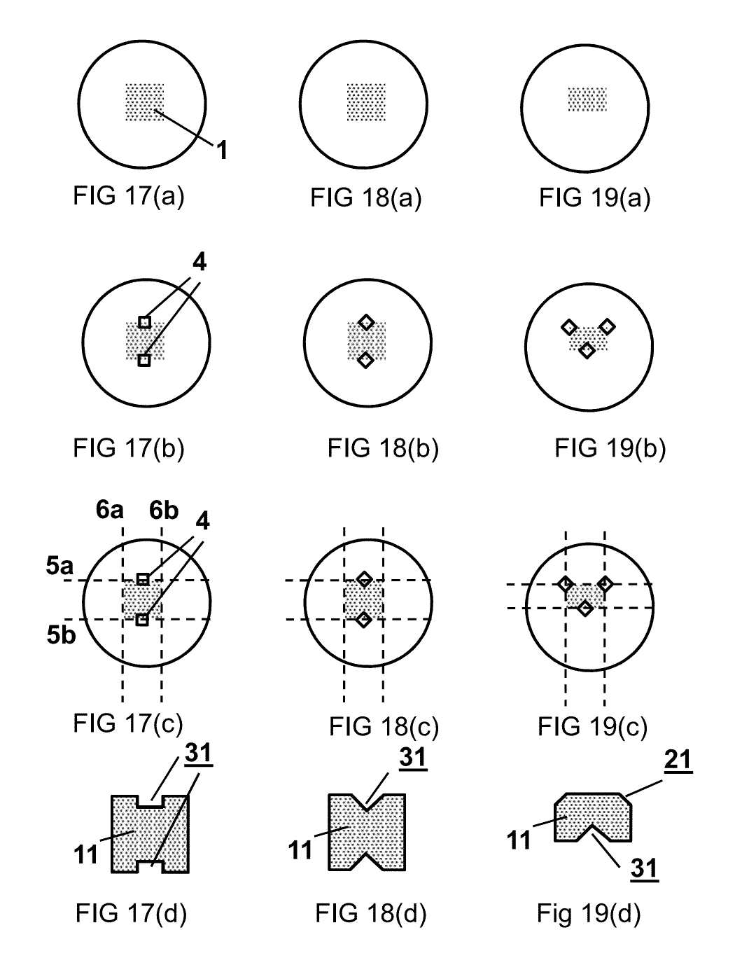

FIG. 17(a) to FIG. 17(d) is a variant of FIG. 14(a) to FIG. 14(d), whereby the two openings 4 have a different position, i.e. not at the corners, resulting in a substantially rectangular semiconductor device having two side cut-outs 31, in the embodiment illustrated two rectangular side cut-outs, shown in FIG. 17(d). In the example shown, the opening 4 has a substantially square cross-section in a plane parallel to the substrate, but that is not absolutely required, and other openings 4 can also be used, e.g. openings with a triangular or circular cross-section.

In the example shown, the cut-outs 31 are located on opposite sides of the semiconductor device 11, but that is not required, and the cut-outs 31 may also be located on adjacent sides of the otherwise rectangular shape.

FIG. 18(a) to FIG. 18(d) is a variant of FIG. 17(a) to FIG. 17(d), whereby the two openings 4 have a different orientation, in particular in the embodiment illustrated located under 45° with respect to the openings 4 shown in FIG. 17, resulting in a substantially rectangular semiconductor device 11 having two triangular side cut-outs 31 as shown in FIG. 18(d).

In another variant of FIG. 17 (not shown), only one of the sides 3 has a side cut-out 31.

In another variant of FIG. 17 (not shown), a single side 3 has two or more cut-outs 31.

In another variant of FIG. 17 (not shown), three of the sides 3 have a cut-out 31.

In another variant of FIG. 17 (not shown), four of the sides 3 have a cut-out 31.

FIG. 19(a) to FIG. 19(d) is a variant of FIG. 12(a) to FIG. 12(d), whereby the three openings 4 have a different position, resulting in a substantially rectangular semiconductor device 11 having two truncated corners 21 and one side cut-out 31 shown in FIG. 19(d). It is noted that the three openings 4 have the same orientation (here: 45° with respect to the cutting lines 5,6), but other orientations can also be used. Moreover, not all openings need to have the same orientation.

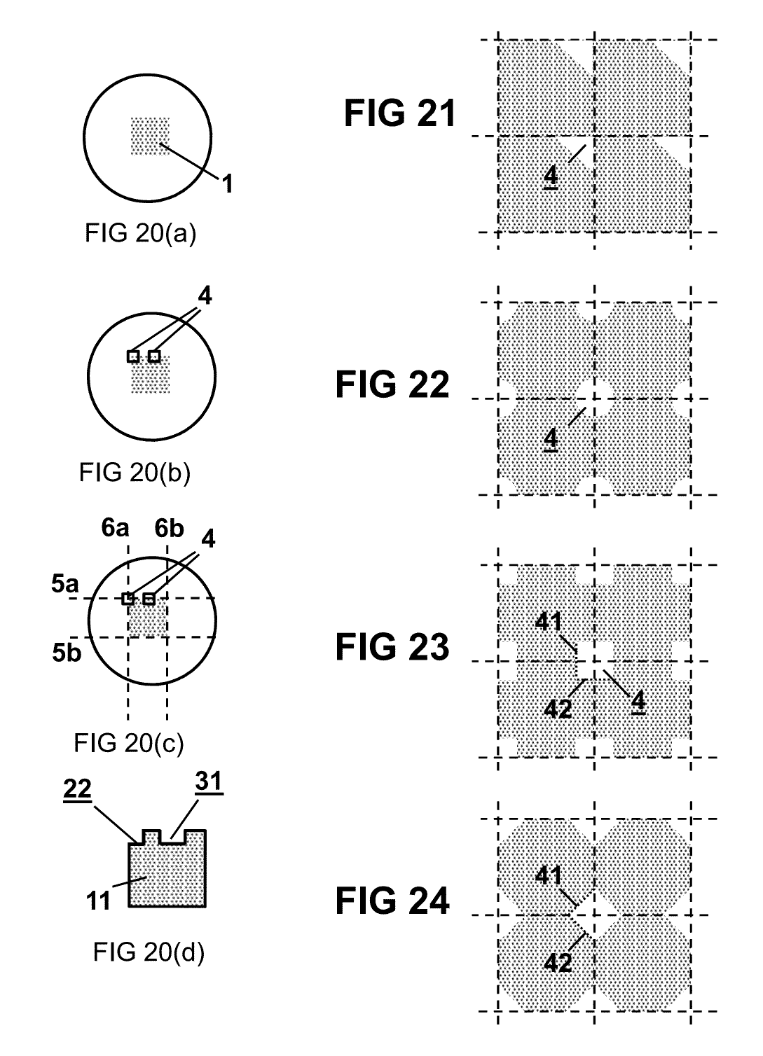

FIG. 20(a) to FIG. 20(d) is a variant of FIG. 14(a) to FIG. 14(d), whereby one of the openings 4 has a different position, resulting in a substantially rectangular semiconductor device 11 having one corner cut-out 22 and one side cut-out 31, as shown in FIG. 20(d).

Although in the examples above, only openings 4 with a square cross-section in a plane parallel to the substrate were used, it will be clear to the person skilled in the art that an opening 4 with another cross-section can also be used, for example a triangular or hexagonal or circular or elliptical or octagonal cross-section, or any other suitable shape.

Although the method of the present invention was explained in the examples of FIG. 10 to FIG. 20 only for a single semiconductor device 11, it is clear that the method can also be used for cutting out a plurality of semiconductor devices 11 from a substrate, e.g. from a wafer. In that case, there would of course be a plurality of openings 4 in the substrate, so that preferably each of the semiconductor devices, e.g. silicon dies, would have the same truncated corners 21 and/or corner cut-outs 22 and/or side cut-outs 31. A method of producing such a plurality of substantially rectangular semiconductor dies 11, each semiconductor die having at least one corner truncation 21 and/or at least one corner cut-outs 22 and/or at least one side cut-out 31, would comprise the steps of: a) providing a semiconductor wafer; b) making a plurality of openings 4 through the semiconductor substrate by means of etching, at least one opening 4 for each semiconductor die; c) dicing the wafer along a first plurality of parallel lines 5, and along a second plurality of parallel lines 6, perpendicular to the first plurality of lines 5, wherein each of said openings 4 is at least passed by one of the lines of the first and/or second plurality of cutting lines 5, 6. This is further illustrated by some examples in FIG. 21 to FIG. 24.

FIG. 21 shows an opening pattern that can be used in a method to produce four semiconductor dies, each having one corner truncation 21, like in FIG. 10(d). The openings 4 have a substantially triangular, e.g. triangular cross-section in a plane parallel to the substrate.

FIG. 22 shows an opening pattern that can be used in a method to produce four semiconductor dies, each having four corner cut-outs 22. The center opening 4 has a circular cross-section in a plane parallel to the substrate.

FIG. 23 shows an opening pattern that can be used in a method to produce four semiconductor dies, each having four corner cut-outs 22. The center opening 4 has a square cross-section in a plane parallel to the substrate. The sides 41, 42 of the square center opening are parallel to the cutting lines 5,6. This pattern can be used to produce four devices as shown in FIG. 16(d).

FIG. 24 shows an opening pattern that can be used in a method to produce four semiconductor dies, each having four truncated corners 21. The center opening 4 has a square cross-section in a plane parallel to the substrate. The sides 41, 42 of the square center opening include an angle of 45° with respect to the cutting lines 5, 6. This pattern can be used to produce four devices as shown in FIG. 13(d).

1. A method of producing a substantially rectangular semiconductor device having at least one corner truncation and/or at least one corner cut-outs and/or at least one side cut-out, comprising the steps of:
a) providing a semiconductor substrate;
b) making at least one opening through the semiconductor substrate by means of etching;
c) cutting the substrate along at least a first pair of parallel lines, and along a second pair of parallel lines perpendicular to the first pair, wherein at least one line of the first pair and/or the second pair passes through said opening.

2. The method according to claim 1,
wherein in step c) the at least one opening is passed by at least one line of the first pair, and also by at least one line of the second pair.

3. The method according to claim 1,
wherein step b) comprises making at least two openings through the semiconductor substrate by means of etching;
and wherein in step c) each opening is passed by at least one line of the first and/or second pair.

4. The method according to claim 1,
wherein step b) comprises making at least three openings through the semiconductor substrate by means of etching;
and wherein in step c) each opening is passed by at least one line of the first and/or second pair.

5. The method according to claim 1,
wherein step b) comprises making at least four openings through the semiconductor substrate by means of etching;
and wherein in step c) each opening is passed by one line of the first pair and by one line of the second pair.

6. The method according to claim 1, wherein the at least one opening has a substantially triangular or rectangular or square or circular cross-section in a plane parallel to the substrate.

7. The method according to claim 6, wherein the opening has a substantially square shape, and wherein the sides of said square cross-section are substantially parallel to the lines of step c.

8. The method according to claim 6, wherein the opening has a substantially square shape, and wherein the sides of said square cross-section have an angle of about 45° with respect to the cutting lines of step c.

9. The method according to claim 1, wherein step b) comprises making the at least one opening using an isotropic etching technique.

10. The method according to claim 1, wherein step b) comprises making the at least one opening using an anisotropic etching technique.

11. The method according to claim 1, wherein step b) comprises making the at least one opening by using at least two different etching steps selected from the group consisting of isotropic front etching, isotropic back etching, anisotropic front etching and anisotropic back etching.

12. Semiconductor device having at least one corner truncation and/or at least one corner cut-out and/or at least one side cut-out, primarily formed by etching.

13. A method of mounting, in a transistor outline package, a substantially rectangular semiconductor device having at least one corner truncation and/or at least one corner cut-out and/or at least one side cut-out, the method comprising:
a) providing a transistor outline package, having at least two elongated legs and at least two corresponding internal wire connection points;
b) providing a substantially rectangular semiconductor device having at least one truncated corner and/or at least one corner cut-out and/or at least one side cut-out, made by a method according to claim 1;
c) positioning the semiconductor device in a plane substantially perpendicular to the elongated legs of the transistor outline package, such that at least one of the wire connection points is located adjacent the at least one corner truncation and/or the at least one corner cut-out and/or the least one side cut-out.

14. Transistor outline package comprising a semiconductor device according to claim 12.
